(19) United States
(12) Patent Application Publication
(10) Pub. No.: US 2003/0115008 A1
(43) Pub. Date: Jun. 19, 2003

(54) Test fixture with adjustable pitch for network measurement

(76) Inventor: Yutaka Doi, Minnetonka, MN (US)

Correspondence Address: ROBERT D. FISH; RUTAN & TUCKER, LLP, P.O. BOX 1950, 611 ANTON BLVD., 14TH FLOOR, COSTA MESA, CA, 92628-1950, US

(21) Appl. No.: 10/033,587

(22) Filed: Dec. 18, 2001

(51) Int. Cl. G06F 19/00; G01R 31/00

(52) U.S. Cl. 702/117

(57) ABSTRACT

A calibrated vector network analyzer (VNA) test system comprising two variable pitch test heads coupled to a VNA. A method for measuring the scattering parameters of at least one two port device under test (DUT) comprising: providing two variable pitch test heads, each test head comprising a signal arm and a ground arm and a cable electrically coupling the test head to a vector network analyzer (VNA); electrically coupling the signal arms of the test heads together; electrically coupling the ground arms of the test heads together; and utilizing the VNA to measure four scattering parameters of a network comprising the coupled test heads; electrically isolating the signal and ground arms of one of the two test heads from those of the other of the two test heads and using the VNA to obtain a reflect coefficient for each test head while the pitch of each test head is set to desired pitch of a port of the at least one DUT; placing each of the test heads in contact with a micro-strip circuit and utilizing the VNA to measure four scattering parameters of the network formed by placing the test heads in contact with the micro-strip circuit; utilizing the measured values to solve a set of 9 equations, the 9 equations containing 9 variables of which 1 is a propagation constant, and 8 are scattering parameters, utilizing the calibrated VNA to measure at least one scattering parameter of the at least one DUT. A method for measuring the scattering parameters of at least one two port DUT comprising: utilizing six reflection coefficients, four transmission coefficients, and a propagation constant to calibrate a VNA having two variable pitch test heads; utilizing the calibrated VNA to measure at least one scattering parameter of the at least one two port DUT.

### FIELD OF THE INVENTION

The field of the invention is vector network analyzer (VNA) test systems and calibration methods.

### BACKGROUND OF THE INVENTION

A two-port device has both input and output terminals each of which consists of signal and ground strips. At each port, there are both incoming and outgoing waves where the amplitude of the wave at a port corresponds to the voltage between the signal and ground strips of the port. FIG. 1 shows that the root mean square voltages of the incoming and outgoing waves at Port 1 and 2 of a device under test (“DUT”) are Vᵢ₁, Vₒ₁, Vᵢ₂, and Vₒ₂ respectively.

The square root of the power of the outgoing wave is expressed as the linear combination of the square root of the power of the incoming wave with coefficients s₁₁, s₁₂, s₂₁, and s₂₂:

vₒ₁=s₁₁vᵢ₁+s₁₂vᵢ₂, (1)

vₒ₂=s₂₁vᵢ₁+s₂₂vᵢ₂, (2)

where

$$\begin{matrix}{v}_{i1} = \frac{{V}_{i1}}{\sqrt{{Z}_{01}}} , & ( 3 ) \\ {v}_{o1} = \frac{{V}_{o1}}{\sqrt{{Z}_{01}}} , & ( 4 ) \\ {v}_{i2} = \frac{{V}_{i2}}{\sqrt{{Z}_{02}}} , and & ( 5 ) \\ {v}_{o2} = \frac{{V}_{o2}}{\sqrt{{Z}_{02}}} . & ( 6 )\end{matrix}$$

As shown in FIG. 1, Z₀₁ and Z₀₂ are the characteristic impedance of the terminal of Port 1 and that of Port 2 respectively.

Equations (1) and (2) may be rewritten as:

$$( \begin{matrix}{v}_{o1} \\ {v}_{o2}\end{matrix} ) = [ \begin{matrix}{s}_{11} & {s}_{12} \\ {s}_{21} & {s}_{22}\end{matrix} ] ( \begin{matrix}{v}_{i1} \\ {v}_{i2}\end{matrix} ) , \qquad ( 7 )$$

where the matrix and its elements are called the S (scattering) matrix and parameters respectively. All numbers in Eq. (7) are all complex numbers expressing the magnitude and phase.

The S matrix determines the relationship between the powers of the incoming and outgoing waves at both ports of the DUT. Thus, the scattering parameters (s₁₁, s₁₂, s₂₁, s₂₂) completely characterize the DUT.

### SUMMARY OF THE INVENTION

A calibrated vector network analyzer (VNA) test system comprising two variable pitch test heads coupled to a VNA. A method for measuring the scattering parameters of at least one two port device under test (DUT) comprising: providing two variable pitch test heads, each test head comprising a signal arm and a ground arm and a cable electrically coupling the test head to a vector network analyzer (VNA); electrically coupling the signal arms of the test heads together; electrically coupling the ground arms of the test heads together; and utilizing the VNA to measure four scattering parameters of a network comprising the coupled test heads; electrically isolating the signal and ground arms of one of the two test heads from those of the other of the two test heads and using the VNA to obtain a reflect coefficient for each test head while the pitch of each test head is set to desired pitch of a port of the at least one DUT; placing each of the test heads in contact with a micro-strip circuit and utilizing the VNA to measure four scattering parameters of the network formed by placing the test heads in contact with the micro-strip circuit; utilizing the measured values to solve a set of 9 equations, the 9 equations containing 9 variables of which 1 is a propagation constant, and 8 are scattering parameters, utilizing the calibrated VNA to measure at least one scattering parameter of the at least one DUT. A method for measuring the scattering parameters of at least one two port DUT comprising: utilizing six reflection coefficients, four transmission coefficients, and a propagation constant to calibrate a VNA having two variable pitch test heads; utilizing the calibrated VNA to measure at least one scattering parameter of the at least one two port DUT.

It is contemplated that the use of variable pitch test heads will reduce testing costs as such heads can be substituted for many expensive pairs of fixed pitch heads. It is also contemplated that the use of variable pitch test heads will result in a time savings, at least in regard to the time that is required for exchanging fixed pitch test heads for differently pitched fixed pitch test heads.

It is also contemplated that variable pitch test heads may be useful to cope with traces on printed circuit board (“PCB”) or integrated circuit (“IC”) packages where the pitches between traces are not uniform or regular. Moreover, the ability of the test heads to achieve wide pitches allow them to be used to probe one-port devices such as inductors, resistors, and capacitors that can not be probed by fixed pitch counterparts with narrow pitches less than 200 μm (micro meters).

Utilizing a micro-strip circuit having an exposed ground plane/surface is thought to facilitate calibration of a VNA utilizing variable pitch test heads as the surface provides a point of contact for a test head for a wide variety of pitches. Preferred micro-strip circuits will comprise an exposed, substantially planar, copper layer comprising two pads electrically isolated from the remainder of the layer to facilitate calibration of variable pitch test heads.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a prior art illustration of the various relationships between incoming and outgoing waves on a two port DUT.

FIG. 1A is a prior art illustration of the application of a forward transmission test to a two port DUT.

FIG. 1B is a prior art illustration of the application of a reverse transmission test to a two port DUT.

FIG. 1C is a prior art illustration of the application of a one-port test to a DUT.

FIG. 1D is a prior art schematic showing a two port network/system consisting of a pair of error two ports, X and Y, and a DUT.

FIG. 2 is a schematic showing two cascaded two port networks, C₁ and C₂.

FIG. 3 illustrates a cascaded network comprising two VNA networks X and Y as utilized during THRU calibration.

FIG. 4 illustrates two VNA networks as utilized during REFLECT calibration.

FIG. 5 illustrates the relationship between input and output waves at a first port during REFLECT calibration.

FIG. 6 illustrates the relationship between input and output waves at a first port during REFLECT calibration.

FIG. 7 illustrates two VNA networks as utilized during a prior art LINE calibration.

FIG. 8A shows a variable pitch test head according to the present invention.

FIG. 8B is a detailed view of the test head of FIG. 8A.

FIG. 9 shows the relationship of two variable pitch test heads during THRU testing according to the present invention.

FIG. 10 shows the relationship of two variable pitch test heads during REFLECT testing according to the present invention.

FIG. 11 is a perspective view of a micro-strip circuit utilized during LINE testing according to the present invention.

FIG. 12 is a cutaway view of the micro-strip circuit of FIG. 11.

FIG. 13 shows the relationship between two variable pitch test heads and the micro-strip circuit of FIGS. 11 and 12 during LINE testing.

### DETAILED DESCRIPTION

Use of a VNA to Determine Scattering Parameters—2 Port Test

A vector network analyzer (“VNA”) is used for determining the scattering parameters of a DUT. The parameters of the DUT are measured while the DUT is inserted between a pair of test heads each of which is coupled to a different port of the DUT and a different port of the VNA. The test heads, like the ports of the DUT, typically each comprise both a ground terminal (“the ground”) and a signal terminal (“the signal”). The test head is generally connected directly to the ground and signal terminals of the DUT port, and to the VNA port via a cable and connector.

The set of four scattering parameters (s₁₁, s₁₂, s₂₁, s₂₂) the VNA measures on a two-port DUT typically consists of reflection (s₁₁, s₂₂) and transmission (s₁₂, s₂₁) coefficients at each of the ports. The coefficients are determined by applying an RF signal to a port with the result that a portion of the RF signal is transmitted through the DUT and appears as an output on the other port of the DUT, while a second portion of the signal is reflected back to the port to which the signal was applied to.

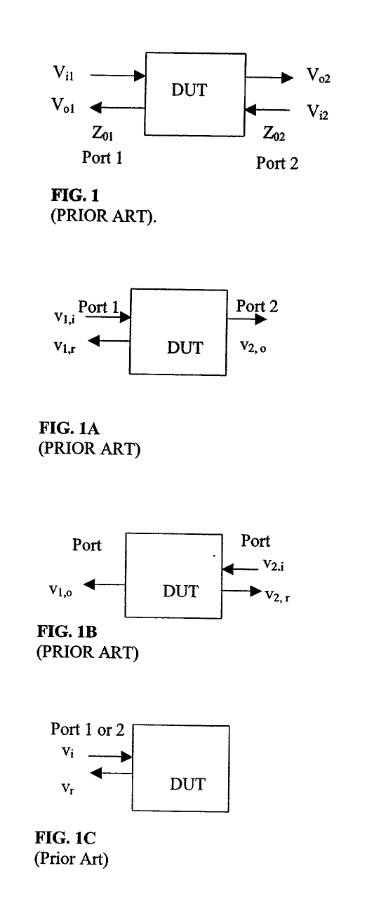

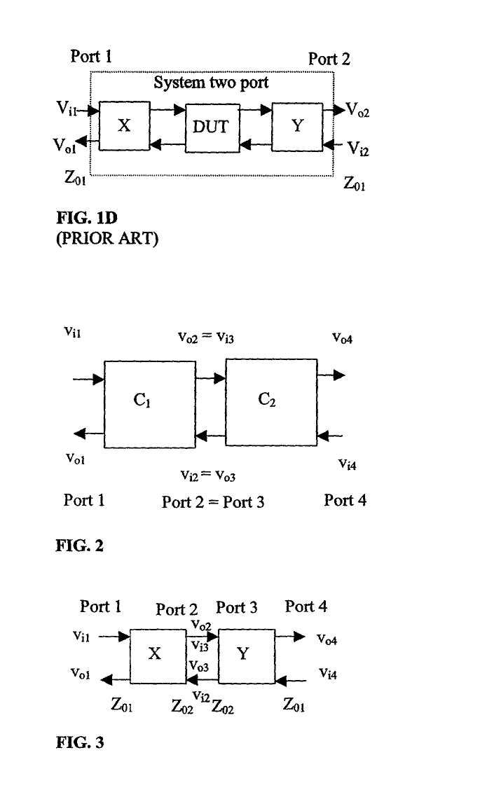

Referring to FIG. 1A, if an RF signal is being applied to Port 1, the reflection coefficient of Port 1 is defined as the ratio of the root mean square (“rms”) voltage amplitude v_{1,r} of the reflected RF wave at Port 1 to the rms voltage amplitude v_{1,i} of the incoming RF wave at Port 1. The transmission coefficient of Port 1 is defined as the ratio of the rms voltage amplitude v_{2,o} of the transmitted RF wave at Port 2 to the rms voltage amplitude v_{1,i} of the incoming RF wave at Port 1, if the characteristic impedance is the same for Port 1 and Port 2. It should be noted that the referenced rms voltages are all complex numbers with the phase angles and absolute values as the amplitudes.

After the measurements are made for one port, the equivalent measurements are made at the second port. Referring to FIG. 1B, if an RF signal is being applied to Port 2, the reflection coefficient of Port 2 is defined as the ratio of the rms voltage amplitude v_{2,r} of the reflected RF wave at Port 2 to the rms voltage amplitude v_{2,i} of the incoming RF wave at Port 2. The transmission coefficient of Port 2 is defined as the ratio of the rms voltage amplitude v_{1,o} of the transmitted RF wave at Port 1 to the rms voltage amplitude v_{2,i} of the incoming RF wave at Port 2.

Testing to obtain the transmission coefficients of a first DUT port is sometimes referred to as the “forward transmission test”, while the subsequent transmission testing of the second DUT port is referred to as the “reverse transmission test”. For the purposes of this disclosure, the testing depicted in FIG. 1 with RF signal directed from Port 1 to Port 2 will be designated the forward test while the testing with RF signal directed from Port 2 to Port 1 will be designated the reverse test. It is important that a matched load be coupled to the end of the transmission line connected to Port 2 during the forward transmission test in order to avoid any reflection at Port 2 coming from the end of the transmission line. The same should be arranged for the reverse transmission test by switching a matched load to the end of the transmission line connected to Port 1.

Use of a VNA to Determine Scattering Parameters—1 Port Test

A one-port test of a DUT is also possible. In the one-port test, as only a single port is available for test, the DUT is characterized by a single reflection coefficient rather than by both a reflection and transmission coefficient. Referring to FIG. 1C, the reflection coefficient is defined as the ratio of the rms voltage amplitude vᵣ of the reflected RF wave either at Port 1 or 2 to the rms voltage amplitude vᵢ of the incoming RF wave to the port.

Error Correction

Actually, instead of measuring only a DUT, a VNA measures total scattering parameters of a system consisting of a DUT, and VNA networks X and Y at Port 1 and 2 as shown in FIG. 2, because it is impossible to place the sensors of the VNA right at the DUT ports being measured. Hence, in order to measure the scattering parameters for the DUT alone (eliminate the instrument and fixture uncertainties), both sets of scattering parameters for VNA networks X and Y at Port 1 and 2 need to be known to be eliminated from the entire system. The two sets of four scattering parameters (eight total) of VNA networks X and Y at Port 1 and Port 2 can be determined from the system measurements by inserting standards in place of a DUT. This procedure is typically referred to as VNA calibration. Once the S matrices of networks X and Y are known (possibly only internally in the VNA), it is possible to extract the S matrix of the DUT

Cascade Matrices

It is not convenient to express cascaded two ports by S matrices the product of which does not yield the S matrix of the combined network. Hence, the C (cascade) matrix is introduced:

$$( \begin{matrix}{v}_{o1} \\ {v}_{i1}\end{matrix} ) = ( \begin{matrix}{c}_{11} & {c}_{12} \\ {c}_{21} & {c}_{22}\end{matrix} ) ( \begin{matrix}{v}_{i2} \\ {v}_{o2}\end{matrix} ) , \qquad ( 8 )$$

where the cascade matrix C is expressed as

$$C = \frac{1}{{s}_{21}} ( \begin{matrix}- {Δ}_{s} & {s}_{11} \\ - {s}_{22} & 1\end{matrix} ) \qquad ( 9 )$$

and

Δₛ=s₁₁s₂₂−s₁₂s₂₁. (10)

Any C matrix can be converted to an S matrix using the following equation:

$$S = \frac{1}{{c}_{22}} ( \begin{matrix}{c}_{12} & {Δ}_{c} \\ 1 & - {c}_{21}\end{matrix} ) \qquad ( 11 )$$

where

Δ_{c}=c₁₁c₂₂−c₁₂c₂₁. (12)

Using two C matrices, the C matrix of the cascaded two ports are expressed as a product of the matrices C₁ and C₂ as shown in FIG. 2:

$$\begin{matrix}( \begin{matrix}{v}_{o1} \\ {v}_{i1}\end{matrix} ) = {C}_{1} ( \begin{matrix}{v}_{i2} \\ {v}_{o2}\end{matrix} ) , and & ( 13 ) \\ ( \begin{matrix}{v}_{o3} \\ {v}_{i3}\end{matrix} ) = {C}_{2} ( \begin{matrix}{v}_{i4} \\ {v}_{o4}\end{matrix} ) . & ( 14 )\end{matrix}$$

Since vₒ₂=vᵢ₃ and vᵢ₂=vₒ₃ in the case of the common characteristic impedance for ports 2 and 3, the combination of Eqs. (13) and (14) results in

$$( \begin{matrix}{v}_{o1} \\ {v}_{i1}\end{matrix} ) = {C}_{1} {C}_{2} ( \begin{matrix}{v}_{i4} \\ {v}_{o4}\end{matrix} ) = C ( \begin{matrix}{v}_{i4} \\ {v}_{o4}\end{matrix} ) . \qquad ( 15 )$$

Using the cascade matrix, any cascaded two ports can be represented as a product of the cascade matrices. Then by determining the C matrices of the error two ports from the calibration, the C matrix of the DUT is extracted from the C matrix of the cascaded network including the DUT and a couple of error two ports. The S matrix of the DUT is then converted from its C matrix.

VNA Measurement of Network Comprising DUT, X, and Y Networks

A VNA measures voltages of incoming and outgoing waves at the two ports of the system two-port consisting of error two ports, X and Y, and a two port DUT. Vᵢ₁ and Vᵢ₂ are the voltages of the incoming waves at Port 1 and Port 2 of the system two-port respectively. Vₒ₁ and Vₒ₂ are the voltages of the outgoing waves at Port 1 and Port 2 respectively. The characteristic impedance, Z₀₁, is common at Port 1 and Port 2.

Eq. (8) can be rewritten for the system two port:

$$( \begin{matrix}\frac{{V}_{o1}}{\sqrt{{Z}_{01}}} \\ \frac{{V}_{i1}}{\sqrt{{Z}_{01}}}\end{matrix} ) = ( \begin{matrix}{c}_{11} & {c}_{12} \\ {c}_{21} & {c}_{22}\end{matrix} ) ( \begin{matrix}\frac{{V}_{i2}}{\sqrt{{Z}_{01}}} \\ \frac{{V}_{o2}}{\sqrt{{Z}_{01}}}\end{matrix} ) , \qquad ( 16 )$$

which is reduced to

$$( \begin{matrix}{V}_{o1} \\ {V}_{i1}\end{matrix} ) = ( \begin{matrix}{c}_{11} & {c}_{12} \\ {c}_{21} & {c}_{22}\end{matrix} ) ( \begin{matrix}{V}_{i2} \\ {V}_{o2}\end{matrix} ) , \qquad ( 17 )$$

because the same denominator \sqrt{Z₀₁} drops out. Hence the voltages, Vᵢ₁, Vᵢ₂ Vₒ₁, and Vₒ₂ appear to solve the coefficients c₁₁, c₁₂, c₂₁, and c₂₂. However, Eq. (17) represents nothing but two simultaneous equations that are not sufficient to solve four unknowns, c₁₁, c₁₂, c₂₁, and c₂₂. Therefore, the following method is improvised.

During the forward measurement, the signal is applied to Port 1 and Port 2 is connected to a load whose impedance is Z₀₁ to eliminate any reflection, i.e., Vᵢ₂=0. Then Eq. (17) yields

Vₒ₁=c₁₂Vₒ₂, (18)

and

Vᵢ₁=c₂₂Vₒ₂ (19)

determining c₁₂ and c₂₂ respectively.

On the other hand, during the reverse measurement, the signal is applied to Port 2 and Port 1 is terminated with a matched load eliminating Vᵢ₁. Then Eq. (17) results in

Vₒ₁′=c₁₁Vᵢ₂′+c₁₂Vₒ₂′ (20)

and

0=c₂₁Vᵢ₂′+c₂₂Vₒ₂′ (21)

where the superscript, prime, for the voltages distinguishes them from those for the forward measurement. Since c₁₂ and c₂₂ are solved, Eqs. (20) and (21) can solve both c₁₁ and c₂₁.

TRL Calibration

One method of VNA calibration is the THRU-REFLECT-LINE (“TRL”) method. The TRL calibration method originated from the National Institute of Standards and Technology and is a frequently used calibration method for VNAs. The TRL method uses three calibration steps, each of which has a separate standard associated with it. The first step is the “THRU” step, the second step is the “REFLECT” step, and the third step is the “LINE” step. Typical TRL calibration methods require one to know or measure the characteristic impedance of the standard/delay line used during the LINE step. However, as provided below, determining the characteristic impedance need not be determined in all instances. It is contemplated that not having to determine the characteristic impedance is particularly beneficial when calibrating a VNA using variable pitch test heads.

TRL Calibration—THRU

For the THRU step, the two test head of the VNA are connected together directly with the signal tip of one test head tied to the signal tip of the other test head, and the ground tip of one test head tied to the ground tip of the other test head. (Alternatively, both test heads can be placed on a transmission line of a negligibly short length.) Coupling the test heads together forms a cascaded network of both VNA networks X and Y at Port 1 and 2 as shown in FIG. 3. Port 1 of X is connected with one of VNA ports and Port 2 of X is connected directly with Port 3 of Y. Port 4 of Y is connected with another port of VNA. The characteristic impedance of Port 1 is Z₀₁ and that of Port 2 is Z₀₂. The characteristic impedance of Port 3 is Z₀₂ and that of Port 2 is Z₀₁. Using the cascaded network as a DUT, the two-port measurement gives a set of four scattering parameters each of which can be expressed as an equation that includes the eight parameters of the VNA networks X and Y at Port 1 and 2.

Suppose that the two cascaded two port error matrices, X and Y, are expressed as:

$$\begin{matrix}X = ( \begin{matrix}{x}_{11} & {x}_{12} \\ {x}_{21} & {x}_{22}\end{matrix} ) , and & ( 22 ) \\ Y = ( \begin{matrix}{y}_{11} & {y}_{12} \\ {y}_{21} & {y}_{22}\end{matrix} ) . & ( 23 )\end{matrix}$$

The vectors at Port 1 and Port 2 are expressed by

$$\begin{matrix}( \begin{matrix}{v}_{o1} \\ {v}_{i1}\end{matrix} ) = ( \begin{matrix}{x}_{11} & {x}_{12} \\ {x}_{21} & {x}_{22}\end{matrix} ) ( \begin{matrix}{v}_{i2} \\ {v}_{o2}\end{matrix} ) , \\ where & ( 24 ) \\ {v}_{o1} = \frac{{V}_{o1}}{\sqrt{{Z}_{01}}} , & ( 25 ) \\ {v}_{i1} = \frac{{V}_{i1}}{\sqrt{{Z}_{01}}} , & ( 26 ) \\ {v}_{i2} = \frac{{V}_{i2}}{\sqrt{{Z}_{02}}} , \\ and & ( 27 ) \\ {v}_{o2} = \frac{{V}_{o2}}{\sqrt{{Z}_{02}}} . & ( 28 )\end{matrix}$$

The vectors at Port 3 and Port 4 are expressed by

$$\begin{matrix}( \begin{matrix}{v}_{o3} \\ {v}_{i3}\end{matrix} ) = ( \begin{matrix}{y}_{11} & {y}_{12} \\ {y}_{21} & {y}_{22}\end{matrix} ) ( \begin{matrix}{v}_{i4} \\ {v}_{o4}\end{matrix} ) , \\ where & ( 29 ) \\ {v}_{o3} = \frac{{V}_{o3}}{\sqrt{{Z}_{02}}} , & ( 30 ) \\ {v}_{i3} = \frac{{V}_{i3}}{\sqrt{{Z}_{02}}} , & ( 31 ) \\ {v}_{i4} = \frac{{V}_{i4}}{\sqrt{{Z}_{01}}} , \\ and & ( 32 ) \\ {v}_{o4} = \frac{{V}_{o4}}{\sqrt{{Z}_{01}}} . & ( 33 )\end{matrix}$$

Due to the voltage continuity, Vᵢ₂=Vₒ₃ and Vₒ₂=Vᵢ₃. Accordingly, from Eqs. (27)˜(30), vᵢ₂=vₒ₃ and vₒ₂=vᵢ₃. Since vₒ₁ and vᵢ₁ are expressed by vᵢ₄ and vₒ₄ using XY, the product of X and Y is determined from the voltage measurement as mentioned earlier.

TRL Calibration—REFLECT

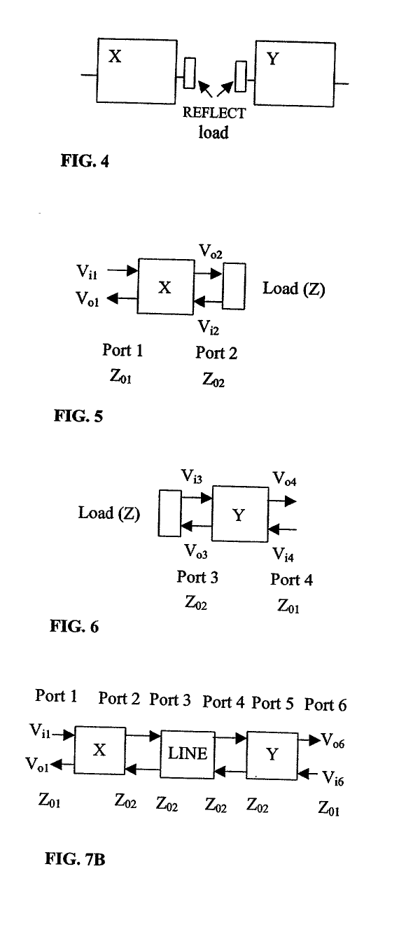

For the REFLECT step, any identical load with a high reflection coefficient (typically open or short circuits) is connected to each test port as shown in FIG. 4 where each error matrix X and Y corresponds to a test port. The exact value of the impedance of the REFLECT load need not be known, because the impedance of the load as expressed by the reflection coefficient at each port is identical and the equation eliminates the REFLECT load impedance. Thus one equation that includes the eight scattering parameters of VNA networks at Port 1 and 2 is obtained.

FIG. 5 shows the REFLECT measurement at one port of VNA. The voltages of incoming and outgoing waves at Port 1 of the error two-port X are Vᵢ₁ and Vₒ₁ respectively. The voltages of incoming and outgoing waves at Port 2 of the error two-port X are Vᵢ₂ and Vₒ₂ respectively. The characteristic impedances at Port 1 and Port 2 are Z₀₁ and Z₀₂ respectively. The load impedance is Z. The load is connected with Port 2 of the error two-port. As before the relation between the vectors of Port 1 and Port 2 is expressed by

$$( \begin{matrix}\frac{{V}_{o1}}{\sqrt{{Z}_{01}}} \\ \frac{{V}_{i1}}{\sqrt{{Z}_{01}}}\end{matrix} ) = ( \begin{matrix}{x}_{11} & {x}_{12} \\ {x}_{21} & {x}_{22}\end{matrix} ) ( \begin{matrix}\frac{{V}_{i2}}{\sqrt{{Z}_{02}}} \\ \frac{{V}_{o2}}{\sqrt{{Z}_{02}}}\end{matrix} ) . \qquad ( 34 )$$

The ratio of Vᵢ₂ to Vₒ₂ is called the reflection coefficient, ρ₂, at Port 2 and is given by (see S. Ramo, J. R. Whinnery, and T. Van Duzer, Fields and Waves in Communication Electronics, 3^{rd}. ed. (Wiley, New York, 1993), p. 220)

$${ρ}_{2} ≡ \frac{{V}_{i2}}{{V}_{o2}} = \frac{Z - {Z}_{02}}{Z + {Z}_{02}} . \qquad ( 35 )$$

Combination of Eqs. (34) and (35) results in

$${ρ}_{2} = \frac{\frac{{V}_{o1}}{{V}_{i1}} {x}_{22} - {x}_{12}}{- \frac{{V}_{o1}}{{V}_{i1}} {x}_{21} + {x}_{11}} . \qquad ( 36 )$$

On the other hand, FIG. 6 shows REFLECT measurement at another port of VNA. The voltages of incoming and outgoing waves at Port 3 of the error two-port X are Vᵢ₃ and Vₒ₃ respectively. The voltages of incoming and outgoing waves at Port 4 of the error two-port X are Vᵢ₄ and Vₒ₄ respectively. The characteristic impedances at Port 3 and Port 4 are Z₀₂ and Z₀₁ respectively. The load impedance is Z. The load is connected with Port 3 of the error two-port. As before the reflection coefficient at Port 3 is given by

$${ρ}_{3} ≡ \frac{{V}_{i3}}{{V}_{o3}} = \frac{Z - {Z}_{02}}{Z + {Z}_{02}} . \qquad ( 37 )$$

Similarly, it is rewritten as

$${ρ}_{2} = {ρ}_{3} = \frac{{y}_{21} + \frac{{V}_{o4}}{{V}_{i4}} {y}_{22}}{{y}_{11} + \frac{{V}_{o4}}{{V}_{i4}} {y}_{12}} . \qquad ( 38 )$$

TRL Calibration—LINE

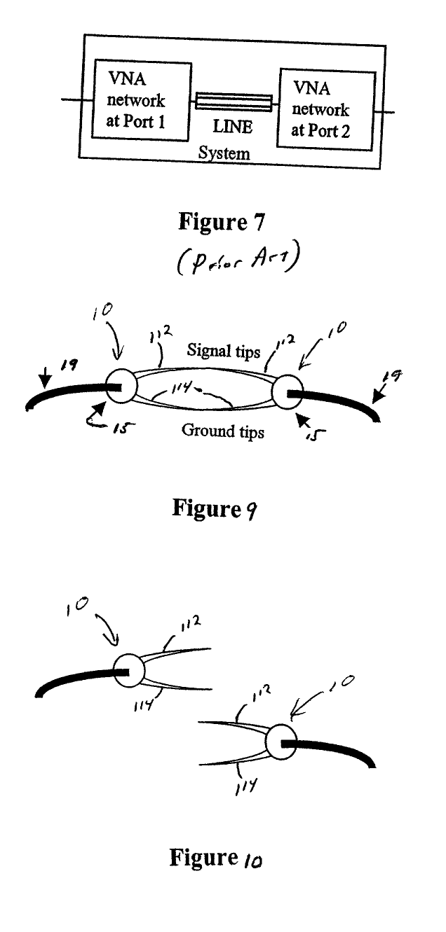

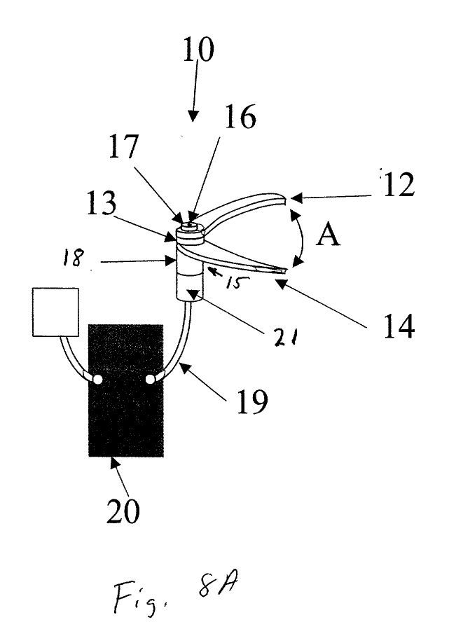

For the LINE step, a short transmission line is inserted between Port 1 and Port 2 for a two-port measurement as shown in FIG. 7. A transmission line is defined from both the characteristic impedance and propagation constant. Although the former can be determined by time domain reflectometry (“TDR”), the latter is not readily obtained. For a short, non-loss transmission line, the propagation constant is reduced to the phase constant that is 2π/λ (wavelength). The wavelength, a ratio of the velocity to the frequency, is not known, since the wave velocity through the transmission line is unknown. Therefore, the phase constant is left as another unknown. The four scattering parameters obtained for the system correspond to four equations each of which is expressed by the phase constant of the line and eight scattering parameters of the VNA networks at Port 1 and 2 and.

LINE calibration is the two port VNA measurement on a pair of error two ports, X and Y, and a transmission line as shown in FIG. 7.

First, for the X two-port, the following equation is established:

$$( \begin{matrix}\frac{{V}_{o1}}{\sqrt{{Z}_{01}}} \\ \frac{{V}_{i1}}{\sqrt{{Z}_{01}}}\end{matrix} ) = ( \begin{matrix}{x}_{11} & {x}_{12} \\ {x}_{21} & {x}_{22}\end{matrix} ) ( \begin{matrix}\frac{{V}_{i2}}{\sqrt{{Z}_{02}}} \\ \frac{{V}_{o2}}{\sqrt{{Z}_{02}}}\end{matrix} ) . \qquad ( 39 )$$

The voltages of incoming and outgoing waves at Port 1 of the error two-port X are Vᵢ₁ and Vₒ₁ respectively. The voltages of incoming and outgoing waves at Port 2 of the error two-port X are Vᵢ₂ and Vₒ₂ respectively. The characteristic impedances at Port 1 and Port 2 are Z₀₁ and Z₀₂ respectively.

Second, for Y two-port, the following equation is established:

$$( \begin{matrix}\frac{{V}_{o5}}{\sqrt{{Z}_{02}}} \\ \frac{{V}_{i5}}{\sqrt{{Z}_{02}}}\end{matrix} ) = ( \begin{matrix}{y}_{11} & {y}_{12} \\ {y}_{21} & {y}_{22}\end{matrix} ) ( \begin{matrix}\frac{{V}_{i6}}{\sqrt{{Z}_{01}}} \\ \frac{{V}_{o6}}{\sqrt{{Z}_{01}}}\end{matrix} ) . \qquad ( 40 )$$

The voltages of incoming and outgoing waves at Port 5 of the error two-port Y are Vᵢ₅₁ and Vₒ₅ respectively. The voltages of incoming and outgoing waves at Port 6 of the error two-port Y are Vᵢ₆ and Vₒ₆ respectively. The characteristic impedances at Port 5 and Port 6 are Z₀₂ and Z₀₁ respectively.

Last, the cascade matrix of LINE is expressed as

$$( \begin{matrix}\frac{{V}_{o3}}{\sqrt{{Z}_{0}}} \\ \frac{{V}_{i3}}{\sqrt{{Z}_{0}}}\end{matrix} ) = ( \begin{matrix}{ⅇ}^{- jβ ⅆ} & 0 \\ 0 & {ⅇ}^{jβ ⅆ}\end{matrix} ) ( \begin{matrix}\frac{{V}_{i4}}{\sqrt{{Z}_{0}}} \\ \frac{{V}_{o4}}{\sqrt{{Z}_{0}}}\end{matrix} ) , \qquad ( 41 )$$

where the voltages of incoming and outgoing waves at Port 4 of LINE are Vᵢ₃ and Vₒ₃ respectively. The voltages of incoming and outgoing waves at Port 4 of LINE are Vᵢ₄ and Vₒ₄ respectively. The characteristic impedance of LINE is Z₀. The propagation constant β is given by

$$β = \frac{2 π}{λ} , \qquad ( 42 )$$

where λ is the wavelength. Both j and d are \sqrt{−1} and the length of the transmission line, LINE respectively.

Combining Eqs. (39)˜(41),

$$( \begin{matrix}{V}_{o1} \\ {V}_{i1}\end{matrix} ) = XLY ( \begin{matrix}{V}_{i6} \\ {V}_{o6}\end{matrix} ) , \qquad ( 43 )$$

where L is the cascade matrix of LINE specified by Eq. (41).

Equation (43) indicates that the cascaded network consisting of X, LINE, and Y two ports can be regarded as a two port and that it is measured by VNA for calculation of the product of XLY.

TRL Calibration—Equation Solution

After performing all three steps, there are nine equations for nine unknowns that therefore can be solved. The equations to be solved are as follows:

(1) THRU

a₁₁=x₁₁y₁₁+x₁₂y₂₁ (44)

a₁₂=x₁₁y₁₂+x₁₂y₂₂ (45)

a₂₁=x₂₁y₁₁+x₂₂y₂₁ (46)

a₂₂=x₂₁y₁₂+x₂₂y₂₂ (47)

Values a₁₁, a₁₂, a₂ₗ, and a₂₂ are measured on the cascade two ports of X and Y.

(2) REFLECT

Combination of Eqs. (36) and (38) yields

$$\frac{- {x}_{12} + {r}_{1} {x}_{22}}{{x}_{11} - {r}_{1} {x}_{21}} = \frac{{y}_{21} + {r}_{2} {y}_{22}}{{y}_{11} + {r}_{2} {y}_{12}} , \qquad ( 48 )$$

where r₁ and r₂ are the reflection coefficients measured for X and Y ports respectively.

(3) LINE

Combination of Eqs. (41) and (43) yields

b₁₁=x₁₁y₁₁e^{-jβd}+x₁₂y₂₁e^{jβd}, (49)

b₁₂=x₁₁y₁₂e^{-jβd}+x₁₂y₂₂e^{jβd}, (50)

b₂₁=x₂₁y₁₁e^{-jβd}+x₂₂y₂₁e^{jβd}, (51)

and

b₂₂=x₂₁y₁₂e^{-jβd}+x₂₂y₂₂e^{jβd}, (52)

where b₁₁, b₁₂, b₂₁, and b₂₂ are measured elements of the cascade matrix of X, LINE, and Y two ports.

Since there are nine equations, Eqs. (44)˜(52), for nine unknowns, x₁₁, x₁₂, x₂₁, x₂₂, y₁₁, y₁₂, y₂₁, y₂₂, and β, those unknown are solved. Therefore, the two error cascade matrices, X and Y, are to be completely determined.

Variable Pitch Test Head

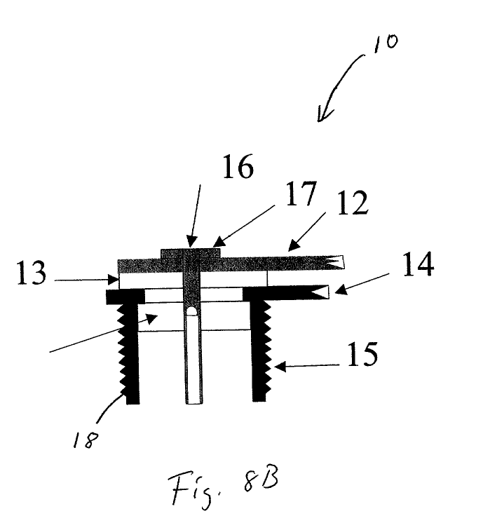

Referring to FIGS. 8A and 8B, a variable pitch head 10 of the present invention includes a signal arm 12 and a ground arm 14 which are respectively connected to the signal pin 16 and ground sleeve 18 of a SMA female connector 15. Head 10 also comprises a base ring 17, and an insulator ring 13 separating signal arm 12 and ground arm 14. Head 10 is coupled to a VNA 20 via a SMA male connector 21 (engaging SMA female connector 15) and a cable 19. The signal arm 12 can be rotated relative to the ground arm 14 to vary angle A, thus making the pitch adjustable. Although the various components of test head 10 may each be comprised of various suitable materials, it is preferred that the material for the base ring 17 of the test head 10 is brass, and that the insulator ring 13 between the signal pin and the base ring is TEFLON. Both signal and ground arms 12 and 14 are preferably made of brass.

TRL Calibration for a Variable Pitch Test Head

A VNA utilizing a pair of variable pitch test heads 10 can be calibrated using the TRL method as follows:

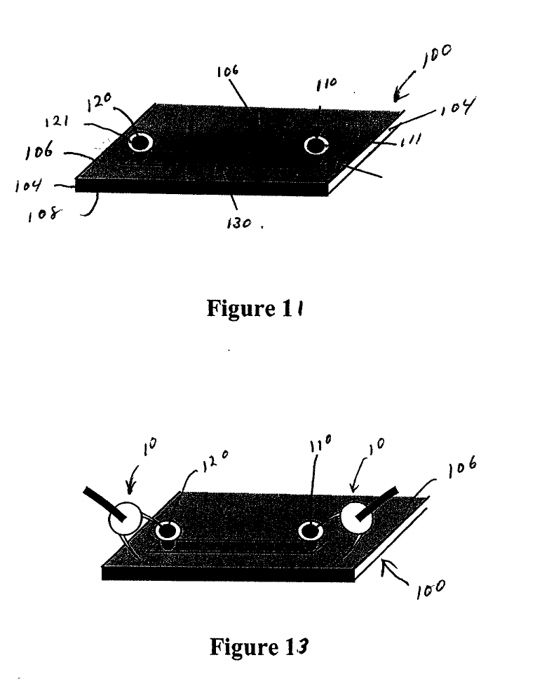

1. THRU calibration. As shown in FIG. 9, the test heads 10 are connected together with the tips of signal arms 12 tied together, and the tips of ground arms 14 tied together to form a cascaded network as shown in FIG. 5. The two-port measurement is applied to the cascaded network to obtain a set of four scattering parameters each of which can be expressed as an equation that includes the eight parameters of the two VNA networks corresponding to each of the pair of test heads.

2. REFLECT calibration. The two variable pitch test heads are isolated from each other as shown in FIG. 10. Once isolated from each other, the one-port test previously described in reference to FIG. 1C is used to obtain a reflect coefficient for each test head and one more equation that include the eight parameters of the two VNA networks.

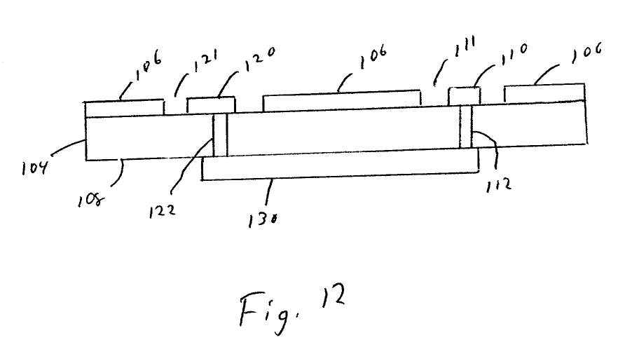

3. LINE calibration. First, a micro-strip circuit 100 is prepared as shown in FIGS. 11 and 12. A copper plate layer 106 on a first surface of a substrate 104 includes pads 110 and 120 that are insulated from the remainder of the copper plated surface 106 by rings 111 and 121. Pads 110 and 120 are connected using vias 112 and 122 to both ends of a strip-line 130 formed on an opposing surface 108 of substrate 104. Next, the micro-strip line 130 is measured by TDR for the characteristic impedance Z of micro-strip line 130. Finally, as shown in FIG. 13, each signal line 12 is placed on a separate pad 110, 120, and each ground arm 14 is placed on the nod pad portions of copper plate layer 106 (the “ground plain”). Then a two-port measurement is performed to obtain a set of four scattering parameters each of which can be expressed as an equation that includes the eight parameters of the two VNA networks corresponding to each of the pair of test heads and the propagation constant strip line 130.

In total, ten measurements are made and used to obtain nine independent equations containing nine variables/unknown values, eight of which correspond to parameters of the VNA networks at Port 1 and 2 and one of which is a propagation constant. Solution of the equations determines the values of the variables. Since eight of the nine solved parameters are scattering parameters for VNA networks at Port 1 and 2, all four scattering parameters of any DUT are determined.

It should be noted that, once determined, the value for propagation constant β remains constant and may be used in subsequent calibrations of the combination of VNA and variable pitch test heads.

It should be noted that the exact form and/or composition of micro-strip circuit 100 may vary between embodiments. However, preferred embodiments will have a sufficiently large ground plane surface positioned close enough to the contact points for the micro-strip to allow such an embodiment of circuit 100 to be utilized for variable pitch test heads that can be configured to have a large distance between the signal and ground tips of the test head. Preferred micro-strip circuits will comprise an exposed, substantially planar, copper layer comprising two pads electrically isolated from the remainder of the layer to facilitate calibration of variable pitch test heads. Even more preferred micro-strip circuits will utilize a ground plane or other sizeable conductive layer as a shield between the test heads and the micro-strip while the test heads are in contact with the micro-strip circuit such that the conductive layer helps to prevent transmission of signals between the test heads and micro-strip other than through the pads and vias intended to transmit the signal to the micro-strip.

Thus, specific embodiments and applications of test systems incorporating variable pitch test heads and related calibration devices and methods have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A calibrated vector network analyzer (VNA) test system comprising two variable pitch test heads coupled to a VNA.

2. The test system of claim 1 wherein at least one test head comprises:
a sub-miniature-A (SMA) female connector that includes a ground sleeve and signal pin;
a ground arm electrically coupled to the ground sleeve of the SMA female connector;
a signal arm electrically coupled to the signal pin of the SMA female connector;
wherein at least one of the signal arm and ground arm is adapted to be rotated relative to the other arm.

3. The test system of claim 1 further comprising a micro-strip circuit adapted for line calibration of the two variable pitch test heads.

4. The test system of claim 3 wherein the micro-strip circuit comprises:
a copper plate layer on a first surface of a dielectric substrate, the copper plate layer including a ground plane and at least two pads insulated from the ground plane;
a conductor on a second surface of the substrate, the conductor being electrically coupled to two of the at least two pads.

5. The system of claim 1 wherein:
each test head comprises a sub-miniature-A (SMA) female connector that includes a ground sleeve and signal pin; a ground arm electrically coupled to the ground sleeve of the SMA female connector; and a signal arm electrically coupled to the signal pin of the SMA female connector;
at least one of the signal arm and ground arm is adapted to be rotated relative to the other arm;
the system also comprises a micro-strip circuit adapted for line calibration of the two variable pitch test heads;
the micro-strip circuit comprises a copper plate layer on a first surface of a dielectric substrate, the copper plate layer including a ground plane and at least two pads insulated from the ground plane; and a conductor on a second surface of the substrate, the conductor being electrically coupling together two of the at least two pads; and
the signal arm of a first of the two test heads is in electrical contact with a first of the two coupled together pads, the ground arm of the first of the two test heads is in electrical contact with the ground plane, the signal arm of a second of the two test heads is in electrical contact with a second of the two coupled together pads, and the ground arm of the second of the two test heads is in electrical contact with the ground plane.

6. A method for measuring the scattering parameters of at least one two port device under test (DUT) comprising:
providing two variable pitch test heads, each test head comprising a signal arm and a ground arm and a cable electrically coupling the test head to a vector network analyzer (VNA); electrically coupling the signal arms of the test heads together; electrically coupling the ground arms of the test heads together; and utilizing the VNA to measure four scattering parameters of a network comprising the coupled test heads;
electrically isolating the signal and ground arms of one of the two test heads from those of the other of the two test heads and using the VNA to obtain a reflect coefficient for each test head while the pitch of each test head is set to desired pitch of a port of the at least one DUT;
placing each of the test heads in contact with a micro-strip circuit and utilizing the VNA to measure four scattering parameters of the network formed by placing the test heads in contact with the micro-strip circuit;
utilizing the measured values to solve a set of 9 equations, the 9 equations containing 9 variables of which 1 is a propagation constant, and 8 are scattering parameters.
utilizing the calibrated VNA to measure at least one scattering parameter of the at least one DUT.

7. The method of claim 6 wherein the calibrated VNA and variable pitch test heads are subsequently used to obtain a calibrated measurement of at least one scattering parameter of a second DUT having a pitch differing from that of the first DUT, wherein the VNA is recalibrated between the first measurement and second measurement using the propagation constant computed during the first calibration of the VNA.

8. A method for measuring the scattering parameters of at least one two port DUT comprising:
utilizing six reflection coefficients, four transmission coefficients, and a propagation constant to calibrate a VNA having two variable pitch test heads;
utilizing the calibrated VNA to measure at least one scattering parameter of the at least one two port DUT.
